(19) United States
(12) Patent Application Publication
(10) Pub. No.: US 2026/0372054 A1
(43) Pub. Date: Nov. 19, 2026

(54) PAD STRUCTURE FOR A SEMICONDUCTOR DEVICE

(71) Applicant: Micron Technology, Inc., Boise, ID (US)

(72) Inventors: Song GUO, Boise, ID (US); Soichi SUGIURA, Boise, ID (US)

(21) Appl. No.: 19/577,926

(22) Filed: Mar. 25, 2026

Related U.S. Application Data
(60) Provisional application No. 63/808,211, filed on May 19, 2025.

(51) Int. Cl. H10W 20/42; H10W 20/00

(52) U.S. Cl. CPC H10W 20/422; H10W 20/056; H10W 20/081

(57) ABSTRACT

Implementations described herein relate to various structures, integrated assemblies, and memory devices. In some implementations, an apparatus may include an active area, a cell contact structure, and a pad structure. The active area may be encircled by a first dielectric material. The cell contact structure may be encircled by a second dielectric material. The pad structure may extend vertically between the cell contact structure and the active area. The pad structure may include a first region that is in contact with the active area and is encircled by the first dielectric material. The pad structure may also include a second region that is in contact with the cell contact structure and is encircled by the second dielectric material.

### CROSS-REFERENCE TO RELATED APPLICATION

This Patent Application claims priority to U.S. Provisional Patent Application No. 63/808,211, filed on May 19, 2025, entitled “PAD STRUCTURE FOR A SEMICONDUCTOR DEVICE,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a pad structure for a semiconductor device.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell.

FIG. 2 includes a diagrammatic view of an example implementation described herein.

FIG. 3 is a flowchart of an example method of forming an integrated assembly, memory device, or apparatus having a pad structure described herein.

FIGS. 4A-4E are diagrammatic views showing formation of portions of a semiconductor device including the pad structure at example process stages.

FIG. 5 is a diagrammatic view of an example memory device described herein.

### DETAILED DESCRIPTION

As memory device technology continues to scale down in size, various components within the memory device may also be scaled down in size. As the components within the memory devices scale down, there may be challenges related to the physical and electrical characteristics of the cell contacts within the memory device. In particular, the cell contacts may be conductive pathways that establish electrical connections between active areas of the memory device and other circuit components. In some cases, the memory device may include conductive cell contact pads that extend between the cell contacts and the active areas. As the size of the cell contacts and cell contact pads decreases, the resistance between the active areas and the cell contacts, particular at the interfaces of the cell contact pads, may increase.

Some implementations described herein provide a method for manufacturing cell contact pad structures associated with reduced resistance at the interfaces of the cell contact pads. In particular, the method for manufacturing may form memory devices where interfaces of the cell contact pads (which may be resistive) are at higher cross-sectional area locations within the memory device. This may result in a cell contact pad structure with larger, more uniform contact areas that mitigate resistivity at critical junctions.

In some implementations, and as an example, a memory device includes a cell contact pad structure that extends between the cell contact structure and the active area. The active area and the cell contact structure may not be horizontally aligned. Accordingly, the cell contact pad structure may extend both vertically and horizontally between the cell contact structure and the active area. Both a first contact area, between the cell contact pad structure and the active area, and a second contact area, between the cell contact pad structure and the cell contact structure, may be substantially horizontal and circular.

In contrast to other cell contact pad structures, the cell contact pad structures described herein may have increased contact areas and reduced contact resistance. In this way, quality and/or reliability of the semiconductor device is improved. By improving the quality and/or the reliability of the semiconductor device, the reliability of data stored by the semiconductor device may be improved, an energy associated with operating the semiconductor device may be reduced, and a life span of the semiconductor device may be increased.

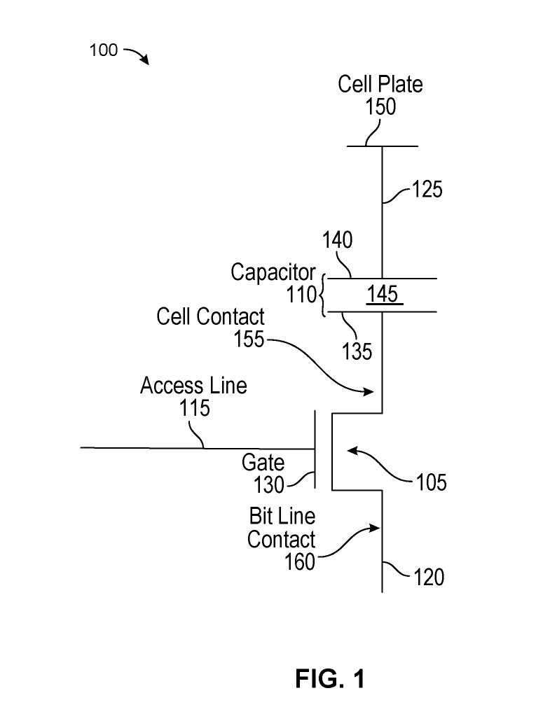

FIG. 1 is a circuit diagram of an example memory cell 100. In some implementations, the memory cell 100 is a ferroelectric memory cell. Alternatively, the memory cell 100 may be a linear dielectric memory cell or a paraelectric memory cell. As shown in FIG. 1, the memory cell 100 may include a transistor 105 (or another type of selection circuit) and a capacitor 110. The memory cell 100 may be accessed (e.g., written to, read from, and/or erased) using signals on a combination of lines that are coupled to the memory cell 100, shown as an access line 115 (sometimes called a “word line”), a bit line 120 (sometimes called a “digit line”), and a plate line 125.

The transistor 105 (sometimes called an access transistor) may include a gate 130. The capacitor 110 includes a bottom electrode 135 and a top electrode 140 separated by an insulator 145. In some implementations, the capacitor is a ferroelectric capacitor, and the insulator 145 is a ferroelectric insulator that comprises, consists of, or consists essentially of ferroelectric material. Alternatively, the capacitor may be a linear dielectric capacitor, and the insulator 145 may be a linear dielectric insulator that comprises, consists of, or consists essentially of linear dielectric material. Alternatively, the capacitor may be a paraelectric capacitor, and the insulator 145 may be a paraelectric insulator that comprises, consists of, or consists essentially of paraelectric material. When the access line 115 is activated (e.g., when a voltage is applied to the access line 115), the gate 130 coupled to the access line 115 may be activated. When the gate 130 is activated, the transistor 105 couples the bit line 120 to the bottom electrode 135 of the capacitor 110. A state of the memory cell 100 may then be written or read via the bit line 120.

The top electrode 140 of the capacitor 110 may be coupled to the plate line 125 and a cell plate 150. To write to (or program) the memory cell 100, the access line 115 may be activated, and a voltage may be applied across the capacitor 110 by controlling the voltage of the top electrode 140 (via the plate line 125 and/or the cell plate 150) and/or the bottom electrode 135 (via the bit line 120).

For a ferroelectric capacitor, the applied voltage creates an electric field, and the atoms in the ferroelectric material of the insulator 145 respond to the electric field to become arranged in a particular state (e.g., a particular orientation or polarization), which is representative of a data state (e.g., a logic “0” state or a logic “1” state). In some implementations, data may be stored using the capacitor 110 by controlling a voltage difference and/or a polarity difference of the capacitor 110 (e.g., of the insulator 145 between the bottom electrode 135 and the top electrode 140). For example, a voltage of the cell plate 150 and the bit line 120 may be controlled. In some implementations, a negative polarity of the insulator 145, as compared to the cell plate 150, results in a logic “0” state being stored in the capacitor 110, and a positive polarity of the insulator 145 as compared to the cell plate 150 results in a logic “1” state being stored in the capacitor 110. For a linear dielectric capacitor or a paraelectric capacitor, the cell plate 150 may grounded, and the capacitor 110 may be charged by applying a voltage to the bottom electrode 135 via the bit line 120.

To read the memory cell 100 (e.g., a state stored by the capacitor 110), the access line 115 may be activated, and a voltage may be applied to the plate line 125. Applying a voltage to the plate line 125 may cause a change in the stored charge on the capacitor 110. The magnitude of the change in stored charge may depend on the stored state of capacitor 110 (e.g., whether the stored state is a logic “1” state or a logic “0” state). This may or may not induce a threshold change in the voltage of the bit line 120 based on the charge stored on the capacitor 110. The change in voltage or lack of change in voltage of the bit line 120 (or a magnitude of the change in voltage) may be used to determine the stored state of the capacitor 110. For example, if the change in voltage satisfies a threshold, then the read operation indicates that a first state was stored in the capacitor 110, whereas if the change in voltage does not satisfy the threshold, then the read operation determines that a second state was stored in the capacitor 110. In some cases, multiple threshold voltages may be used, such as when the capacitor is capable of storing more than two data states (e.g., for a multi-level cell, a triple-level cell, and so on).

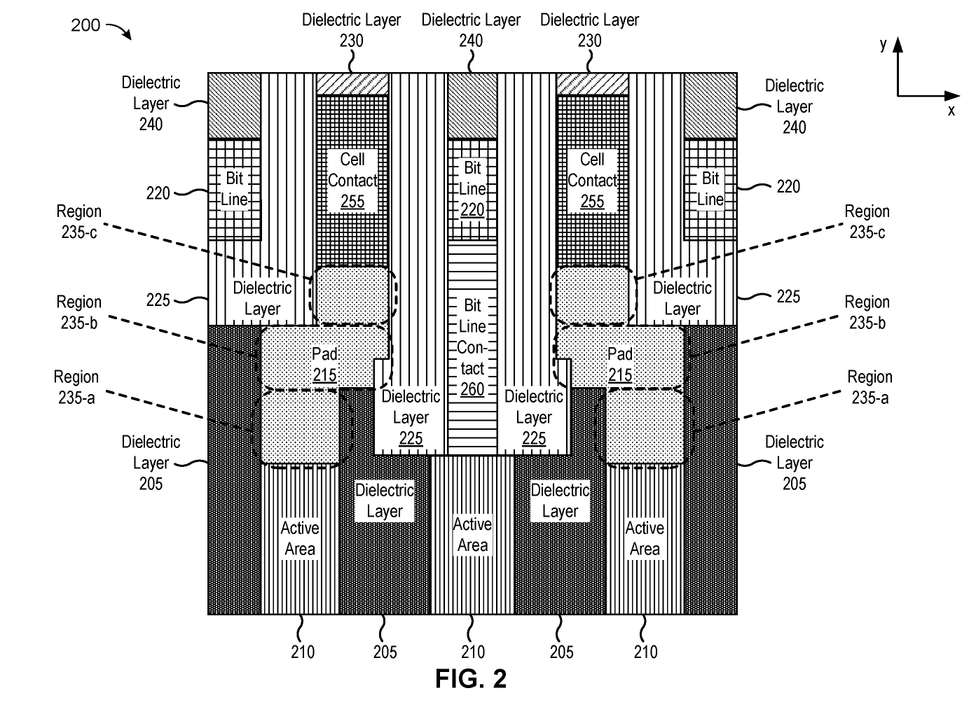

In some implementations, the memory cell 100 is accessed using a cell contact 155 and a bit line contact 160. The cell contact 155 may be part of a connection between the capacitor 110 and the transistor 105, and the bit line contact 160 may be part of a connection between the bit line 120 and the transistor 105. As described in greater detail in connection with FIGS. 2-5, the cell contact 155 may electrically connect with the transistor 105 using a cell contact pad structure that includes a first interface (between the cell contact 155 and the cell contact pad structure) and a second interface (between the cell contact pad structure and the transistor 105) that are both substantially circular.

As indicated above, FIG. 1 is provided as an example. Other examples may differ from what is described with respect to FIG. 1.

FIG. 2 includes a diagrammatic view of an example implementation 200 described herein. The implementation 200, which corresponds to one or more portions of a semiconductor device (e.g., the memory cell 100 of FIG. 1), may include one or more features related to a pad structure for a semiconductor device described herein. The illustrated x-axis is substantially perpendicular to the y-axis.

The dielectric layer 205, positioned at the base, serves as an insulation layer and may include a dielectric material. That is, the dielectric layer 205 may be fabricated from materials such as silicon oxide or silicon nitride and may provide additional electrical insulation necessary for functionality of the semiconductor device. In some implementations, the dielectric layer 205 may correspond to a shallow trench isolation region of the semiconductor device.

The active area 210 may be encircled by the dielectric layer 205. That is, the sidewalls of the active area 210 may be in contact with the sidewalls of the dielectric layer 205. The active area 210 may include a semiconductive layer, and may be fabricated from materials such as polysilicon, gallium arsenide, indium phosphide, or gallium nitride, providing an active area for the semiconductor device. In some implementations, the active area 210 corresponds to source/drain region of a transistor (e.g., a source/drain region of the transistor 105 of FIG. 1). The active area 210 may correspond to a cylinder that is surrounded or encircled by the dielectric layer 205.

The bit line contact 260 may be directly on and in contact with the active area 210. The bit line contact 260 may include a conductive layer or a metallization layer, and may be fabricated from materials such as tungsten, aluminum, or titanium nitride. The bit line contact 260 may provide electrical connectivity with other components of the semiconductor device. In some implementations, the bit line contact 260 corresponds to a bit line contact structure (e.g., the bit line contact 160 of FIG. 1).

The bit line 220 may be directly on and in contact with the bit line contact 260. The bit line 220 may include a conductive layer or a metallization layer, and may be fabricated from materials such as tungsten, aluminum, or titanium nitride. The bit line 220 may provide electrical connectivity with other components of the semiconductor device. In some implementations, the bit line 220 corresponds to a bit line structure (e.g., the bit line 120 of FIG. 1).

A dielectric layer 240 may be directly on and in contact with the bit line 220. The dielectric layer 240 may include a dielectric material. That is, the dielectric layer 240 may be fabricated from materials such as silicon oxide or silicon nitride and provide additional electrical insulation necessary for functionality of the semiconductor device.

The bit line contact 260, the bit line 220, and the dielectric layer 240 may be encircled by a dielectric layer 225. The dielectric layer 225 may serve as an insulation layer and may be fabricated from materials such as silicon oxide or silicon nitride and may provide additional electrical insulation necessary for functionality of the semiconductor device.

The cell contact 255 may also be encircled by the dielectric layer 225. The cell contact 255 may include a conductive layer, and may be fabricated from materials such as tungsten, aluminum, or titanium nitride. In some implementations, the cell contact 255 corresponds to a cell contact structure (e.g., the cell contact 155 of FIG. 1). The cell contact 255 may provide electrical connectivity with other components of the semiconductor device. For example, the cell contact 255 may electrically couple to a capacitive structure (e.g., the capacitor 110 of FIG. 1). A dielectric layer 230 may be directly on and in contact with the cell contact 255. The dielectric layer 230 may include a dielectric material. That is, the dielectric layer 230 may be fabricated from materials such as silicon oxide or silicon nitride and provide additional electrical insulation necessary for functionality of the semiconductor device.

The pad 215 may extend between the active area 210 and the cell contact 255. In some cases, the pad 215 may include a conductive layer, and may be fabricated from materials such as tungsten, aluminum, or titanium nitride. In some other cases, the pad 215 may include a semiconductive layer, and may be fabricated from materials such as an epitaxial silicon wafer, polysilicon, gallium arsenide, indium phosphide, or gallium nitride, among other examples. In some cases, the pad 215 may include an epitaxial material (e.g., a conductive material or a semiconductive material that is formed using an epitaxial growth operation). The pad 215 may be a cell contact pad structure that corresponds to a cell contact pad. The active area 210 and the cell contact 255 may be vertically separated and not horizontally aligned. Accordingly, the pad 215 may extend both vertically and horizontally between the active area 210 and the cell contact 255.

The pad 215 may be directly on and in contact with the active area 210. The interface between the pad 215 and the active area 210 may be substantially circular and horizontal. The cell contact 255 may also be directly on and in contact with the pad 215. The interface between the cell contact 255 and the pad 215 may be substantially circular and horizontal.

The pad 215 may include three regions: the region 235-a, the region 235-b, and the region 235-c. The pad 215 may include an epitaxial layer (e.g., that comprises and epitaxial material) that spans the entire pad 215 (including the region 235-a, the region 235-b, and the region 235-c). The region 235-a may include a portion of the pad 215 that interfaces with the active area 210 and is surrounded and encircled by the dielectric layer 205. Additionally, both the active area 210 and the region 235-a of the pad 215 may extend between a first sidewall of the dielectric layer 205 and a second sidewall of the dielectric layer 205. In some cases, a diameter of the active area 210 and a diameter of the region 235-a may be substantially the same. The region 235-a may be approximately less than 50 nanometers tall (e.g., the region 235-a may extend less than 50 nanometers vertically, in the y-direction).

The region 235-b may include a portion of the pad 215 that does not interface with either the active area 210 or the cell contact 255. The region 235-b may extend laterally beyond the active area 210 (e.g., in the x-direction). That is, while a first sidewall of the region 235-b contacts a sidewall of the dielectric layer 205 (e.g., a same sidewall with which the active area 210 is in contact), a second sidewall of the region 235-b extends laterally or horizontally beyond the sidewall of the active area 210. The second sidewall of the region 235-b may contact a sidewall of the dielectric layer 225. In some cases, the region 235-b may extend laterally between the active area 210 and the cell contact 255. That is, a first sidewall of the region 235-b may be substantially horizontally aligned with a sidewall of the active area 210, and a second sidewall of the region 235-b may be substantially horizontally aligned with a sidewall of the cell contact 255.

The region 235-c may include a portion of the pad 215 that interfaces with the cell contact 255 and is surrounded and encircled by the dielectric layer 225. Additionally, both the active area cell contact 255 and the region 235-c of the pad 215 may extend between a first sidewall of the dielectric layer 225 and a second sidewall of the dielectric layer 225. In some cases, a diameter of the cell contact 255 and a diameter of the region 235-c may be substantially the same. The region 235-c may be approximately less than 50 nanometers tall (e.g., the region 235-c may extend less than 50 nanometers vertically, in the y-direction).

As indicated above, FIG. 2 is provided as an example. Other examples may differ from what is described with regard to FIG. 2.

As described in connection with FIG. 1 and FIG. 2, and in some implementations, an integrated assembly (e.g., the memory cell 100) includes a semiconductor device structure. The semiconductor device structure includes a semiconductive layer (e.g., the active area 210), a first conductive layer over the semiconductive layer (e.g., the pad 215), and a second conductive layer over the first conductive layer (e.g., the cell contact 255). The semiconductive layer may extend horizontally (e.g., along the x-axis) between a first sidewall of a first dielectric layer (e.g., the dielectric layer 205) and a second sidewall of the first dielectric layer. A first portion of the first conductive layer (e.g., the region 235-a) may extend horizontally (e.g., along the x-axis) between the first sidewall of the first dielectric layer and the second sidewall of the first dielectric layer, and a second portion of the first conductive layer (e.g., the region 235-b and the region 235-c), that is above the first portion of the first conductive layer, may extend laterally (e.g., along the x-axis) beyond the semiconductive layer and the second sidewall of the first dielectric layer.

In some other cases, the semiconductor device structure includes a first semiconductive layer (e.g., the active area 210), a second semiconductive layer over the first semiconductive layer (e.g., the pad 215), and a conductive layer over the second semiconductive layer (e.g., the cell contact 255). Here, the first semiconductive layer may extend horizontally (e.g., along the x-axis) between a first sidewall of a first dielectric layer (e.g., the dielectric layer 205) and a second sidewall of the first dielectric layer. A first portion of the second semiconductive layer (e.g., the region 235-a) may extend horizontally (e.g., along the x-axis) between the first sidewall of the first dielectric layer and the second sidewall of the first dielectric layer, and a second portion of the second semiconductive layer (e.g., the region 235-b and the region 235-c), that is above the first portion of the second semiconductive layer, may extend laterally (e.g., along the x-axis) beyond the first semiconductive layer and the second sidewall of the first dielectric layer.

Additionally, or alternatively and in some implementations, an apparatus (e.g., the memory cell 100) includes a capacitive structure (e.g., the capacitor 110), a cell contact structure (e.g., the cell contact 255), and a pad structure (e.g., the pad 215). The active area may be encircled by a first dielectric material (e.g., the dielectric material within the dielectric layer 205). Additionally, the cell contact structure may be encircled by a second dielectric material (e.g., the dielectric material within the dielectric layer 225). The pad structure may extend vertically (e.g., along the y-axis) between the cell contact structure and the active area. The pad structure may include a first region (e.g., the region 235-a) that is in contact with the active area and is encircled by the first dielectric material. The pad structure may also include a second region (e.g., the region 235-c) that is in contact with the cell contact structure and is encircled by the second dielectric material).

The implementations described herein may improve a quality and/or a reliability of a semiconductor device by reducing contact resistance (e.g., cell contact resistance between a cell contact and a cell contact pad). In some cases, reducing the contact resistance of the semiconductor device may improve a reliability of data stored by the semiconductor device, reduce an energy associated with operating the semiconductor device, and improve a life span of the semiconductor device.

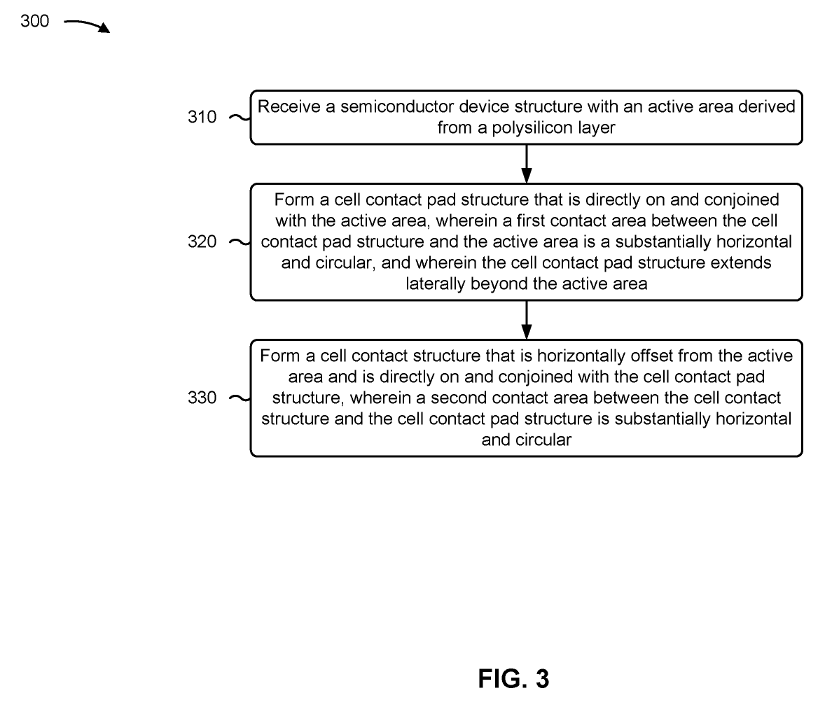

FIG. 3 is a flowchart of an example method 300 of forming an integrated assembly, memory device, or apparatus having a pad structure. In some implementations, one or more process blocks of FIG. 3 may be performed by various semiconductor manufacturing equipment.

As shown in FIG. 3, the method 300 may include receiving a semiconductor device structure with an active area derived from a polysilicon layer (block 310). As further shown in FIG. 3, the method 300 may include forming a cell contact pad structure that is directly on and in contact with the active area, wherein a first contact area between the cell contact pad structure and the active area is a substantially horizontal and circular, and wherein the cell contact pad structure extends laterally beyond the active area (block 320). As further shown in FIG. 3, the method 300 may include forming a cell contact structure that is horizontally offset from the active area and is directly on and in contact with the cell contact pad structure, wherein a second contact area between the cell contact structure and the cell contact pad structure is substantially horizontal and circular (block 330).

The method 300 may include additional aspects, such as any single aspect or any combination of aspects described below and/or in connection with one or more other methods described elsewhere herein.

In a first aspect, forming the cell contact pad structure comprises forming a conductive layer using an epitaxial growth operation.

In a second aspect, alone or in combination with the first aspect, forming the cell contact pad structure comprises forming a cavity that removes a portion of the active area, and forming a portion of the cell contact pad structure in the cavity.

In a third aspect, alone or in combination with one or more of the first and second aspects, the cavity is a first cavity, and the method 300 comprises forming a second cavity that removes portions of a dielectric material that is adjacent to the cell contact structure, wherein forming the first cavity occurs after forming the second cavity.

In a fourth aspect, alone or in combination with one or more of the first through third aspects, the portion of the cell contact pad structure is a first portion of the cell contact pad structure, and forming the cell contact pad structure comprises forming a second portion of the cell contact pad structure in the second cavity.

In a fifth aspect, alone or in combination with one or more of the first through fourth aspects, the cavity is less than approximately 50 nanometers.

In a sixth aspect, alone or in combination with one or more of the first through fifth aspects, forming the cavity comprises performing a chemical vapor etching procedure to form the cavity, or performing a wet etch procedure to form the cavity.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the pad 215, an integrated assembly that includes the pad 215, any part described herein of the pad 215, and/or any part described herein of an integrated assembly that includes the pad 215. For example, the method 300 may include forming the memory cell 100.

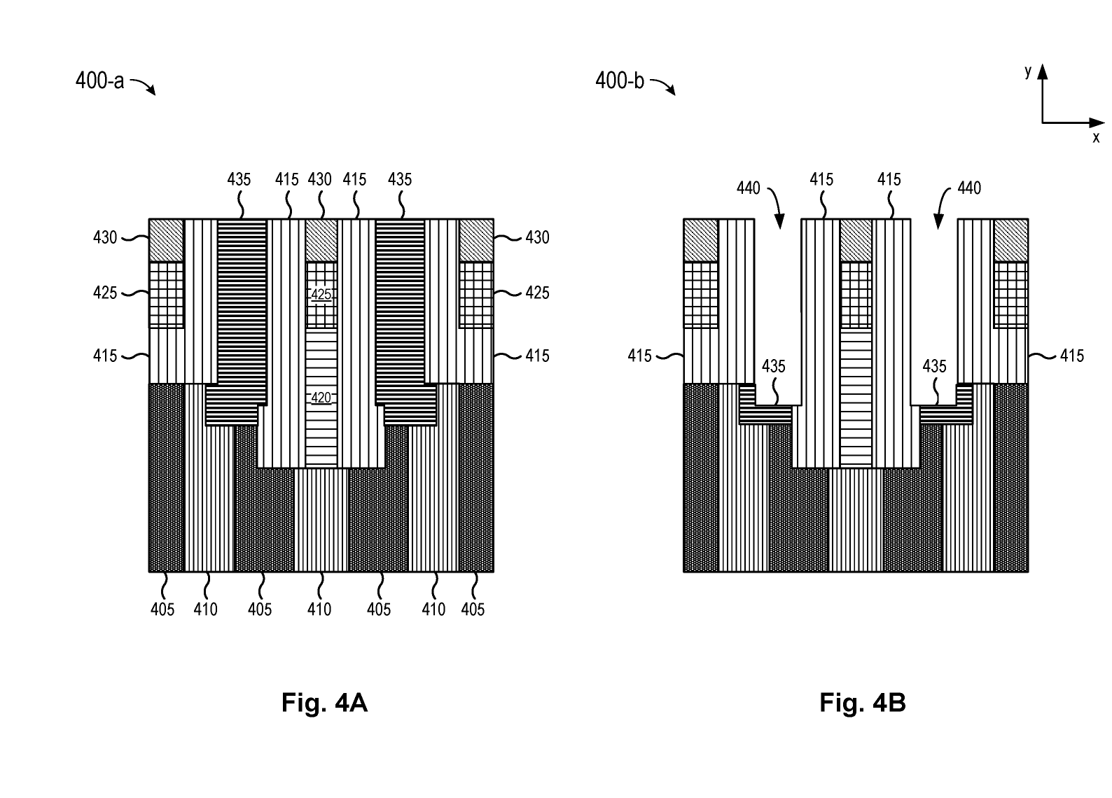

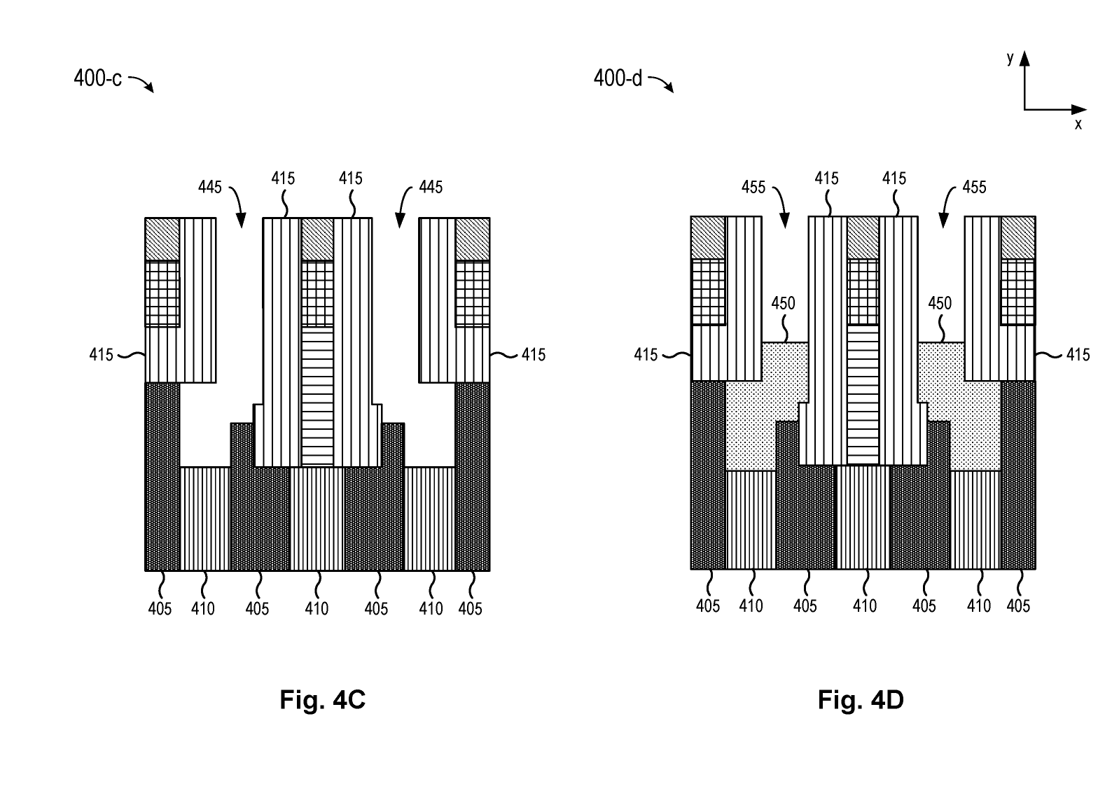

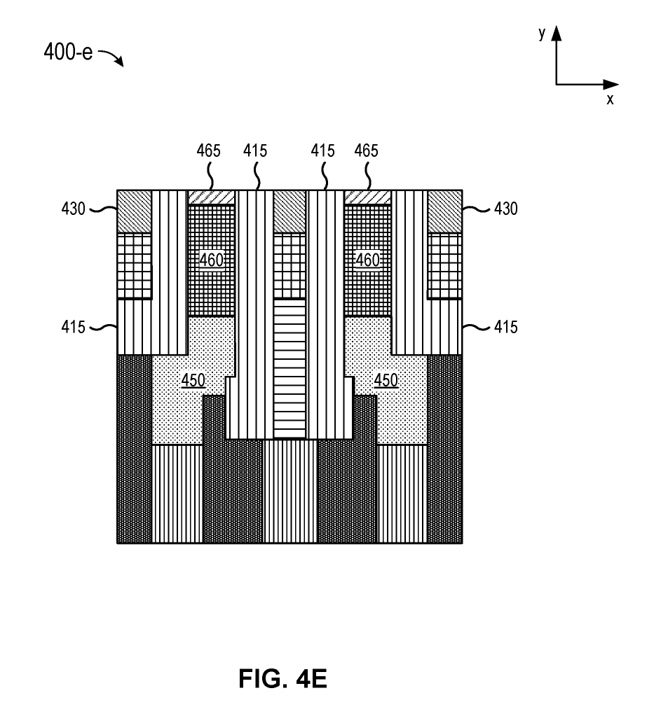

FIGS. 4A-4E are diagrammatic views showing formation of the memory structure illustrated in FIG. 2. That is, FIGS. 4A-4E show example process stages of an example process of forming the memory structure illustrated in FIG. 2. In particular, FIGS. 4A-4E illustrate intermediate structures 400 that are formed during the formation of the memory structure illustrated in FIG. 2. In some implementations, the example process described below in connection with FIGS. 4A-4E may correspond to the method 300 and/or one or more blocks of the method 300. However, the process described below is an example, and other example processes may be used to form the memory structure illustrated in FIG. 2, an integrated assembly that includes the memory structure illustrated in FIG. 2, and/or one or more parts of the memory structure illustrated in FIG. 2 and/or the integrated assembly.

As shown in FIG. 4A, the intermediate structure 400-a may be formed. The intermediate structure 400-a may include a semiconductive device structure. The semiconductive device structure may include a dielectric layer 405, a semiconductive layer 410, a dielectric layer 415, a conductive layer 420, a conductive layer 425, and a dielectric layer 430.

The dielectric layer 405 may comprise, consist of, or consist essentially of an oxide, among other examples. The dielectric layer 405 may form the dielectric layer 205 illustrated with reference to FIG. 2. The semiconductive layer 410 may comprise, consist of, or consist essentially of materials including polysilicon, gallium arsenide, indium phosphide, or gallium nitride, among other examples. That is, the semiconductive layer may correspond to a polysilicon layer. The semiconductive layer 410 may form the active area 210 illustrated with reference to FIG. 2. The dielectric layer 415 may comprise, consist of, or consist essentially of an oxide, among other examples. The dielectric layer 415 may form the dielectric layer 225 illustrated with reference to FIG. 2.

The conductive layer 420 may comprise, consist of, or consist essentially of materials such as tungsten, aluminum, or titanium nitride, among other examples. The conductive layer 420 may form the bit line contact 260 illustrated with reference to FIG. 2. The conductive layer 425 may comprise, consist of, or consist essentially of materials such as tungsten, aluminum, or titanium nitride, among other examples. The conductive layer 425 may form the bit line 260 illustrated with reference to FIG. 2. The dielectric layer 430 may comprise, consist of, or consist essentially of an oxide, among other examples. The dielectric layer 430 may form the dielectric layer 240 illustrated with reference to FIG. 2.

To form the intermediate structure 400-a, the process may include forming (e.g., depositing or growing) a layer 435. In some cases, the layer 435 may correspond to a conductive layer that comprises, consists of, or consists essentially of materials such as tungsten, aluminum, or titanium nitride, among other examples. In some other cases, the layer 435 may correspond to a semiconductive layer that comprises, consists of, or consists essentially of materials such as polysilicon, gallium arsenide, indium phosphide, or gallium nitride, among other examples. In one example of the layer 435 being a semiconductive layer, the layer 435 may comprise, consist of, or consist essentially of an epitaxial silicon wafer.

As shown in FIG. 4B, the intermediate structure 400-b may be formed. In particular, the process may include forming the cavities 440. The formation of cavities 440 may include etching away portions of the layer 435. An etch tool may be used to perform an etch operation that introduces cavities 440 through a process such as a plasma-based etch operation, or a gas-based etch operation. The etch operation may include an anisotropic etch operation, which involves removing material at different rates across multiple different directions, or an isotropic etch operation, which removes material at a same rate across multiple, different directions. The cavities 440 may be defined by sidewalls of the dielectric layer 415 and a top surface of the layer 435. The cavities 440 may be substantially cylindrical.

As shown in FIG. 4C, the intermediate structure 400-c may be formed. In particular, the process may include forming the cavities 445. In some cases, the cavities 445 may be formed based on expanding the cavities 440 of the intermediate structure 400-b. In particular, the cavities 440 may be expanded to extend laterally (e.g., along the x-axis) and vertically (e.g., along the y-axis). The cavities 445 may include a first portion that is substantially cylindrical and extending vertically along the y-axis (e.g., a portion that is defined by the sidewalls of the dielectric layer 415), a portion that is substantially cylindrical and extending horizontally along the x-axis (e.g., a portion that is defined by a bottom surface of the dielectric layer 415 and a top surface of the dielectric layer 405), and a portion that is substantially cylindrical and extending vertically along the y-axis (e.g., a portion that is defined by the sidewalls of the dielectric layer 405).

The cavities 445 may be formed by removing the layer 435 and a portion of the semiconductive layer 410 (e.g., a portion of the semiconductive layer 410 that forms the active area). An etch tool may be used to perform an etch operation that introduces cavities 445. For example, the process may include performing a chemical vapor etching procedure or performing a wet etching procedure to form the cavities 445. The cavities 445 may be defined by sidewalls of the dielectric layer 415, sidewalls of the dielectric layer 405, and a top surface of the semiconductive layer 410.

As shown in FIG. 4D, the intermediate structure 400-d may be formed. In particular, the process may include forming the layer 450. The layer 450 may be formed within portions of the cavities 445 and 440. Based on forming the layer 450, the cavities 455 may also be formed (e.g., within portions of the cavities 440 that are not filled with the layer 450).

A first portion of the layer 450 may be formed within the cavities 445 (e.g., a portion of the layer 450 that is in contact with the sidewalls of the dielectric layer 405, a top surface of the dielectric layer 405, and a bottom surface of the dielectric layer 415). A second portion of the layer 450 may be formed within the cavities 440 (e.g., a portion of the layer 450 that is in contact with sidewalls of the dielectric layer 415).

In some implementations, a deposition tool may be used for deposition of the layer 450, using epitaxial growth techniques, chemical vapor deposition (CVD) techniques, or physical vapor deposition (PVD) techniques. For example, the layer 450 may be formed using an epitaxial growth operation. Here, the layer 450 may include an epitaxial material.

In some cases, the layer 450 may correspond to a conductive layer that comprises, consists of, or consists essentially of materials such as tungsten, aluminum, or titanium nitride, among other examples. In some other cases, the layer 450 may correspond to a semiconductive layer that comprises, consists of, or consists essentially of materials such as polysilicon, gallium arsenide, indium phosphide, or gallium nitride, among other examples. In one example of the layer 450 being a semiconductive layer, the conductive layer 450 may comprise, consist of, or consist essentially of an epitaxial silicon wafer.

The layer 450 may form the pad 215 illustrated with reference to FIG. 2. The layer 450 may be directly on and in contact with the semiconductive layer 410. The layer 450 may extend horizontally between the sidewalls of the dielectric layer 405, extend laterally beyond the semiconductive layer 410, and extend horizontally between the sidewalls of the dielectric layer 415. The contact area between the layer 450 and the semiconductive layer 410 may be substantially horizontal and circular.

As shown in FIG. 4E, the intermediate structure 400-e may be formed. In particular, the process may include forming the conductive layer 460 within the cavities 440. The conductive layer 460 may comprise, consist of, or consist essentially of materials such as tungsten, aluminum, or titanium nitride, among other examples. In some implementations, a deposition tool may be used for deposition of the conductive layer 460 using a PVD technique, an atomic layer deposition (ALD) technique, a CVD technique, an electroplating technique, or another suitable deposition technique.

The process may include forming the dielectric layer 465 within the cavities 440. In some implementations, a deposition tool may be used for deposition of the dielectric layer 465 using a PVD technique, an ALD technique, a CVD technique, an electroplating technique, or another suitable deposition technique. The dielectric layer 465 may comprise, consist of, or consist essentially of an oxide, among other examples. The dielectric layer 465 may form the dielectric layer 230 illustrated with reference to FIG. 2.

As indicated above, the process steps described in connection with FIGS. 4A-4E are provided as examples. Other examples may differ from what is described with respect to FIGS. 4A-4E.

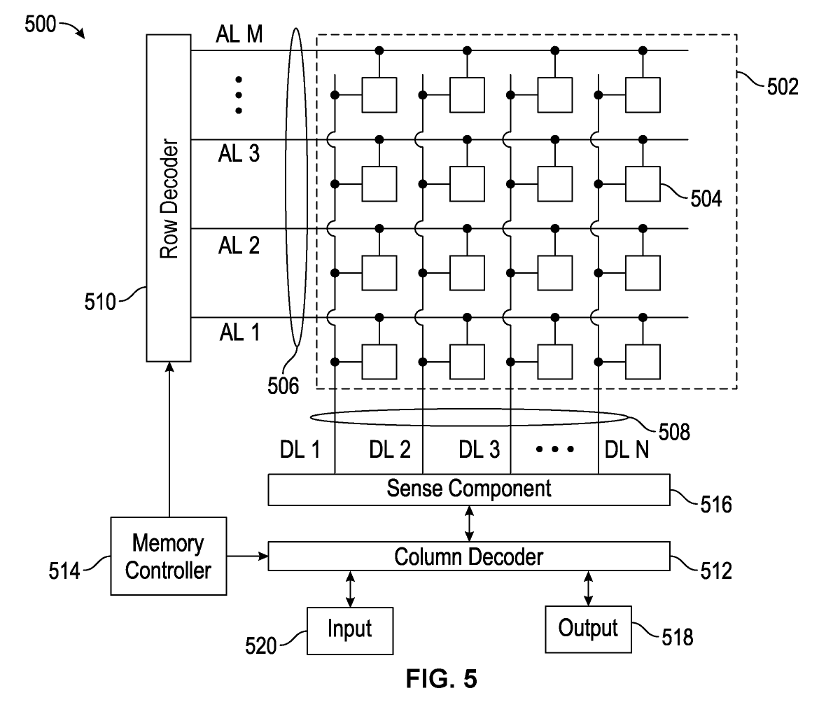

FIG. 5 is a diagrammatic view of an example memory device 500 described herein. The memory device 500 may include a memory array 502 that includes multiple memory cells 504. A memory cell 504 is programmable or configurable into a data state of multiple data states (e.g., two or more data states). For example, a memory cell 504 may be set to a particular data state at a particular time, and the memory cell 504 may be set to another data state at another time. A data state may correspond to a value stored by the memory cell 504. The value may be a binary value, such as a binary 0 or a binary 1, or may be a fractional value, such as 0.5, 1.5, or the like. A memory cell 504 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 504 by activating or selecting the appropriate access line 506 (shown as access lines AL 1 through AL M) and digit line 508 (shown as digit lines DL 1 through DL N). An access line 506 may also be referred to as a “row line” or a “word line,” and a digit line 508 may also be referred to a “column line” or a “bit line.” Activating or selecting an access line 506 or a digit line 508 may include applying a voltage to the respective line. An access line 506 and/or a digit line 508 may comprise, consist of, or consist essentially of a conductive material, such as a metal (e.g., copper, aluminum, gold, titanium, or tungsten) and/or a metal alloy, among other examples. In FIG. 5, each row of memory cells 504 is connected to a single access line 506, and each column of memory cells 504 is connected to a single digit line 508. By activating one access line 506 and one digit line 508 (e.g., applying a voltage to the access line 506 and digit line 508), a single memory cell 504 may be accessed at (e.g., is accessible via) the intersection of the access line 506 and the digit line 508. The intersection of the access line 506 and the digit line 508 may be called an “address” of a memory cell 504.

In some implementations, the logic storing device of a memory cell 504, such as a capacitor, may be electrically isolated from a corresponding digit line 508 by a selection component, such as a transistor. The access line 506 may be connected to and may control the selection component. For example, the selection component may be a transistor, and the access line 506 may be connected to the gate of the transistor. Activating the access line 506 results in an electrical connection or closed circuit between the capacitor of a memory cell 504 and a corresponding digit line 508. The digit line 508 may then be accessed (e.g., is accessible) to either read from or write to the memory cell 504.

A row decoder 510 and a column decoder 512 may control access to memory cells 504. For example, the row decoder 510 may receive a row address from a memory controller 514 and may activate the appropriate access line 506 based on the received row address. Similarly, the column decoder 512 may receive a column address from the memory controller 514 and may activate the appropriate digit line 508 based on the column address.

Upon accessing a memory cell 504, the memory cell 504 may be read (e.g., sensed) by a sense component 516 to determine the stored data state of the memory cell 504. For example, after accessing the memory cell 504, the capacitor of the memory cell 504 may discharge onto its corresponding digit line 508. Discharging the capacitor may be based on biasing, or applying a voltage, to the capacitor. The discharging may induce a change in the voltage of the digit line 508, which the sense component 516 may compare to a reference voltage (not shown) to determine the stored data state of the memory cell 504. For example, if the digit line 508 has a higher voltage than the reference voltage, then the sense component 516 may determine that the stored data state of the memory cell 504 corresponds to a first value, such as a binary 1. Conversely, if the digit line 508 has a lower voltage than the reference voltage, then the sense component 516 may determine that the stored data state of the memory cell 504 corresponds to a second value, such as a binary 0. The detected data state of the memory cell 504 may then be output (e.g., via the column decoder 512) to an output component 518 (e.g., a data buffer). A memory cell 504 may be written (e.g., set) by activating the appropriate access line 506 and digit line 508. The column decoder 512 may receive data, such as input from input component 520, to be written to one or more memory cells 504. A memory cell 504 may be written by applying a voltage across the capacitor of the memory cell 504.

The memory controller 514 may control the operation (e.g., read, write, re-write, refresh, and/or recovery) of the memory cells 504 via the row decoder 510, the column decoder 512, and/or the sense component 516. The memory controller 514 may generate row address signals and column address signals to activate the desired access line 506 and digit line 508. The memory controller 514 may also generate and control various voltages used during the operation of the memory array 502.

In some implementations, the memory device 500 includes the pad structure 215 and/or an integrated assembly that includes the pad structure 215. For example, the memory array 502 may include the pad structure 215 and/or an integrated assembly that includes the pad structure 215. Additionally, or alternatively, the memory cell 504 may include a memory cell described elsewhere herein.

As indicated above, FIG. 5 is provided as an example. Other examples may differ from what is described with respect to FIG. 5.

In some implementations, an integrated assembly includes a semiconductor device structure, comprising: a semiconductive layer extending horizontally between a first sidewall of a first dielectric layer and a second sidewall of the first dielectric layer; a first conductive layer over the semiconductive layer, wherein a first portion of the first conductive layer extends horizontally between the first sidewall of the first dielectric layer and the second sidewall of the first dielectric layer, and wherein a second portion of the first conductive layer, that is above the first portion of the first conductive layer, extends laterally beyond the semiconductive layer and the second sidewall of the first dielectric layer; and a second conductive layer over the first conductive layer.

In some implementations, an apparatus includes an active area encircled by a first dielectric material; a cell contact structure encircled by a second dielectric material; and a pad structure that extends vertically between the cell contact structure and the active area, the pad structure comprising: a first region that is in contact with the active area and is encircled by the first dielectric material, and a second region that is in contact with the cell contact structure and is encircled by the second dielectric material.

In some implementations, a method includes receiving a semiconductor device structure with an active area derived from a polysilicon layer; forming a cell contact pad structure that is directly on and in contact with the active area, wherein a first contact area between the cell contact pad structure and the active area is a substantially horizontal and circular, and wherein the cell contact pad structure extends laterally beyond the active area; and forming a cell contact structure that is horizontally offset from the active area and is directly on and in contact with the cell contact pad structure, wherein a second contact area between the cell contact structure and the cell contact pad structure is substantially horizontal and circular.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element’s relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” All ranges described herein are inclusive of numbers at the ends of those ranges, unless specifically indicated otherwise. As used herein, the term “formed” may, depending on the context, refer to a state or a position of a first feature relative to a second feature, and does not imply any specific method or sequence of formation.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
a semiconductor device structure, comprising:
a semiconductive layer extending horizontally between a first sidewall of a first dielectric layer and a second sidewall of the first dielectric layer;
a first conductive layer over the semiconductive layer,
wherein a first portion of the first conductive layer extends horizontally between the first sidewall of the first dielectric layer and the second sidewall of the first dielectric layer, and
wherein a second portion of the first conductive layer, that is above the first portion of the first conductive layer, extends laterally beyond the semiconductive layer and the second sidewall of the first dielectric layer; and
a second conductive layer over the first conductive layer.

2. The integrated assembly of claim 1, wherein:
the second portion of the first conductive layer extends laterally between a third sidewall of a second dielectric layer and a fourth sidewall of the second dielectric layer; and
the second conductive layer extends laterally between the third sidewall of the second dielectric layer and the fourth sidewall of the second dielectric layer.

3. The integrated assembly if claim 2, wherein a height of the first portion of the first conductive layer is less than approximately 50 nanometers.

4. The integrated assembly of claim 1, wherein:
a first interface between the first conductive layer and the semiconductive layer is horizontal; and
a second interface between the first conductive layer and the second conductive layer is horizontal.

5. The integrated assembly of claim 1, wherein a height of the second portion of the first conductive layer is less than approximately 50 nanometers.

6. The integrated assembly of claim 1, wherein the first conductive layer comprises an epitaxial material.

7. The integrated assembly of claim 1, wherein the first conductive layer comprises tungsten, aluminum, or titanium nitride.

8. The integrated assembly of claim 1, wherein the semiconductive layer comprises polysilicon, gallium arsenide, indium phosphide, and gallium nitride.

9. An apparatus, comprising:
an active area encircled by a first dielectric material;
a cell contact structure encircled by a second dielectric material; and
a pad structure that extends vertically between the cell contact structure and the active area, the pad structure comprising:
a first region that is in contact with the active area and is encircled by the first dielectric material; and
a second region that is in contact with the cell contact structure and is encircled by the second dielectric material.

10. The apparatus of claim 9, wherein the cell contact structure is not horizontally aligned with the active area.

11. The apparatus of claim 9, wherein the pad structure comprises a third region that extends between the first region and the second region.

12. The apparatus of claim 11, wherein the pad structure comprises an epitaxial layer that spans the first region of the pad structure, the second region of the pad structure, and the third region of the pad structure.

13. The apparatus of claim 9, wherein:
a first contact area between the pad structure and the active area is substantially circular; and
a second contact area between the pad structure and the cell contact structure is substantially circular.

14. A method, comprising:
receiving a semiconductor device structure with an active area derived from a polysilicon layer;
forming a cell contact pad structure that is directly on and in contact with the active area, wherein a first contact area between the cell contact pad structure and the active area is a substantially horizontal and circular, and wherein the cell contact pad structure extends laterally beyond the active area; and
forming a cell contact structure that is horizontally offset from the active area and is directly on and in contact with the cell contact pad structure, wherein a second contact area between the cell contact structure and the cell contact pad structure is substantially horizontal and circular.

15. The method of claim 14, wherein forming the cell contact pad structure comprises:
forming a conductive layer using an epitaxial growth operation.

16. The method of claim 14, wherein forming the cell contact pad structure comprises:
forming a cavity that removes a portion of the active area; and
forming a portion of the cell contact pad structure in the cavity.

17. The method of claim 16, wherein the cavity is a first cavity, and wherein the method further comprises:
forming a second cavity that removes portions of a dielectric material that is adjacent to the cell contact structure, wherein forming the first cavity occurs after forming the second cavity.

18. The method of claim 17, wherein the portion of the cell contact pad structure is a first portion of the cell contact pad structure, and wherein forming the cell contact pad structure comprises:
forming a second portion of the cell contact pad structure in the second cavity.

19. The method of claim 16, wherein the cavity is less than approximately 50 nanometers.

20. The method of claim 16, wherein forming the cavity comprises:
performing a chemical vapor etching procedure to form the cavity; or
performing a wet etch procedure to form the cavity.
